(19) United States
(12) Patent Application Publication
(10) Pub. No.: US 2026/0040601 A1
(43) Pub. Date: Feb. 5, 2026

(54) GROUP III-N DEVICE INCLUDING A HYDROGEN-BLOCKING LAYER

(71) Applicant: TEXAS INSTRUMENTS INCORPORATED, Dallas, TX (US)

(72) Inventors: Dong Seup Lee, Allen, TX (US); Jackson Bauer, Rowlett, TX (US)

(21) Appl. No.: 18/788,650

(22) Filed: Jul. 30, 2024

(51) Int. Cl. H01L 29/778; H01L 23/31; H01L 29/20; H01L 29/40; H01L 29/66

(52) U.S. Cl. CPC H10D 30/475; H01L 23/3171; H10D 30/015; H10D 64/111; H10D 62/8503

(57) ABSTRACT

Semiconductor devices including one or more hydrogen-blocking layers are described. In one example, a semiconductor device comprises a semiconductor substrate including a source region, a gate region, a drain region, and a drain access region, where a heterojunction structure is disposed over the semiconductor substrate. The heterojunction structure includes a buffer layer over the semiconductor substrate and a barrier layer over the buffer layer. A p-doped III-N layer is disposed over the barrier layer in the gate region and a gate electrode is formed over the p-doped III-N layer. A first hydrogen-blocking layer is disposed over the gate electrode where the first hydrogen-blocking layer is configured to arrest diffusion of hydrogen into the p-doped III-N layer from a dielectric layer formed after forming the gate electrode.

### FIELD OF THE DISCLOSURE

Disclosed implementations relate generally to the field of group III-N semiconductor devices and their fabrication.

### BACKGROUND

Group III nitride materials (also referred to as III-N materials) possess a unique combination of physical and electrical properties found to be beneficial in modern microelectronics and optoelectronics. Among these properties are wide bandgap, high saturated drift velocity and breakdown voltage, high thermal conductivity, robust chemical and thermal stability, etc. Due to these characteristics, III-N materials are being considered as promising materials for fabrication of powerful high-frequency transistors capable of functioning at high temperatures and in hostile environments. Whereas advances in III-N devices and their fabrication continue to grow apace, several lacunae remain, thereby requiring further innovation as will be set forth hereinbelow.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

In one example, a semiconductor device comprises a semiconductor substrate including a source region, a gate region, a drain region, and a drain access region, where a heterojunction structure is disposed over the semiconductor substrate. The heterojunction structure includes a buffer layer over the semiconductor substrate and a barrier layer over the buffer layer. A p-doped III-N layer is disposed over the barrier layer in the gate region and a gate electrode is formed over the p-doped III-N layer. A hydrogen-blocking layer is disposed over the gate electrode. In some arrangements, the hydrogen-blocking layer is operable to arrest diffusion of hydrogen into the p-doped III-N layer—e.g., from a dielectric layer formed after forming the p-doped III-N layer.

In one example, a method of fabricating a semiconductor device is disclosed. The method comprises, among others, forming a heterojunction structure over a semiconductor substrate including a source region, a gate region, a drain region, and a drain access region between the gate region and the drain region, the heterojunction structure including a buffer layer over the semiconductor substrate and a barrier layer over the buffer layer; forming a p-doped III-N layer over the barrier layer in the gate region; forming a gate electrode over the p-doped III-N layer; and forming a hydrogen-blocking layer over the gate electrode.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure are described in the following Detailed Description taken in connection with the appended claims and with reference to the attached drawing Figures in which:

FIGS. 1A-1N depict cross-sectional views of a semiconductor device including a GaN device at various stages of a process flow according to an example of the present disclosure;

FIGS. 2A-2C are flowcharts of methods of fabricating a semiconductor device according to some examples of the present disclosure; and

FIGS. 3A-3L depict cross-sectional views of a semiconductor device including a GaN device at various stages of a process flow according to an example of the present disclosure.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of the present disclosure will be set forth below in the context of improving performance characteristics of semiconductor devices based on Group III nitride materials, also referred to as III-N materials, such as gallium nitride (GaN) devices.

GaN devices, e.g., GaN transistors, provide certain performance advantages over silicon, including lower on-state resistance (e.g., drain-source resistance or R_{DSON}), lower switching losses, and improved breakdown voltage, among others. GaN transistors include a hetero epitaxy structure with a junction between materials of different bandgaps (e.g., a heterojunction structure), such as aluminum gallium nitride (AlGaN) and gallium nitride, to provide a 2-dimensional electron gas (2DEG) formed within the AlGaN/GaN hetero epitaxy structure that is used for device operation—e.g., forming a channel of the GaN device. The 2-dimensional electron gas (2DEG) may be referred to as a 2DEG channel. Depletion mode (DMODE) GaN transistors are normally on, whereas enhancement mode (EMODE) GaN transistors are normally off. In some examples, EMODE GaN transistors include a gate stack with a p-type doped gallium nitride (p-GaN) layer that depletes the 2DEG beneath the gate at zero or negative gate bias. In some examples, the p-GaN layer may comprise a GaN layer doped with magnesium (Mg) or other p-type dopants. Applying a positive gate voltage enhances the 2DEG under the gate and turns the EMODE GaN device on to allow current flow between the source and drain.

In some examples, a GaN device may be formed with one or more GaN layers over a suitable semiconductor substrate, e.g., including a silicon substrate, where the GaN layers may form a heterojunction structure over the semiconductor substrate. To address various deleterious effects of charge trapping, such as current collapse, increased dynamic on-resistance, etc., one or more surface passivation layers may be provided over the heterojunction structure. Further, one or more field plate (FP) structures may be provided in some examples to mitigate the effects of concentrated electric fields in a GaN device, e.g., at the edges of a gate electrode of the device. Where FP structures and/or surface passivation layers are implemented, dielectric films having a high dielectric constant (high κ), e.g., silicon nitride (SiN) films having k values ranging from around 7 to around 10, may be provided in order to suppress charge traps and/or reduce susceptibility to high electric fields.

SiN layers used for providing dielectric separation for FP structures and/or for passivating surface states in certain GaN devices may constitute material compositions that include hydrogen. During high temperature processes, e.g., annealing processes used in device contact formation, hydrogen may diffuse into the p-GaN layer of a GaN device, where the diffused hydrogen may react with the dopants, e.g., Mg, and form a deactivated dopant complex that reduces the effect of the dopants in the operation of the device. Accordingly, the diffused hydrogen in the p-GaN layer may cause deterioration of the device's electrical characteristics such as reduced threshold voltage (Vₜₕ) and transconductance (gₘ), increased punch-through leakage, etc.

Examples of the present disclosure recognize the foregoing challenges and provide an architecture for integrating diffusion barrier layers in a GaN process flow, where the diffusion barrier layers may be advantageously configured to prevent, arrest or otherwise reduce diffusion of hydrogen from high κ dielectric layers (e.g., SiN layers) into a p-GaN layer of the device—e.g., during high temperature processes. In some arrangements, one or more layers of aluminum oxide (Al₂O₃), aluminum nitride (AlN) and/or a combination thereof may be formed using a suitable deposition process, e.g., atomic layer deposition (ALD) or atomic layer epitaxy (ALE), physical vapor deposition (PVD), etc., that may be operable as hydrogen diffusion barrier layers, also referred to as hydrogen-blocking layers or simply blocking layers for purposes of the present disclosure.

In some arrangements, a blocking layer may be formed prior to forming a SiN layer that may otherwise cause and/or contribute to potential diffusion of hydrogen into a p-GaN layer in a subsequent thermal process but for the presence of the blocking layer. In some arrangements, therefore, multiple blocking layers may be provided in a device at various stages of a process flow depending on the SiN layers used as passivation layers and/or FP dielectric layers (e.g., layers providing dielectric separation for FP structures). As the risk of deactivating dopants in the p-GaN layer is mitigated due to the presence of hydrogen-blocking layers, high κ dielectric materials may be used for forming passivation layers and FP dielectric layers without negatively impacting the device performance. Whereas the examples herein may provide various structures, materials and processes that may engender these and other beneficial effects, no particular result is a requirement unless explicitly recited in a particular claim.

As will be set forth in detail below, the formation of hydrogen-blocking layers may be integrated in a GaN process flow at different stages depending on whether a gate electrode is formed prior to the formation of source/drain electrodes of a device (e.g., in a “gate first” process) or after the formation of the source/drain electrodes (e.g., in a “gate last” process). Although hydrogen-blocking layers may be more beneficial in a gate first process because high temperature ohmic contact annealing processes are implemented after the formation of hydrogen-containing dielectric layers (which surround or overlie the gate stack including p-GaN layer), a gate last process may also include blocking layers for providing additional robustness in certain GaN implementations.

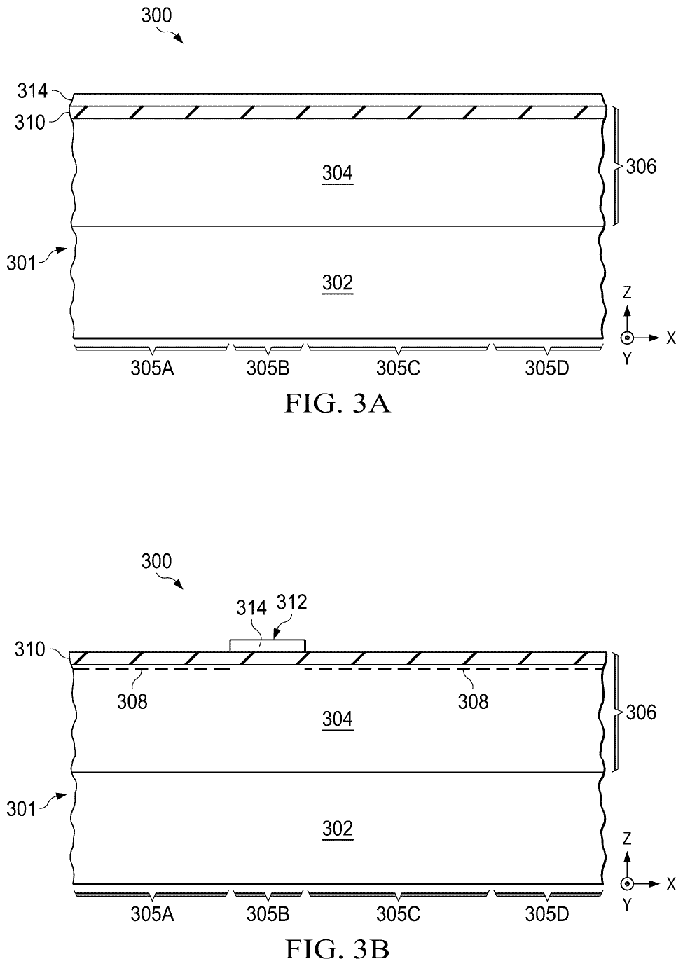

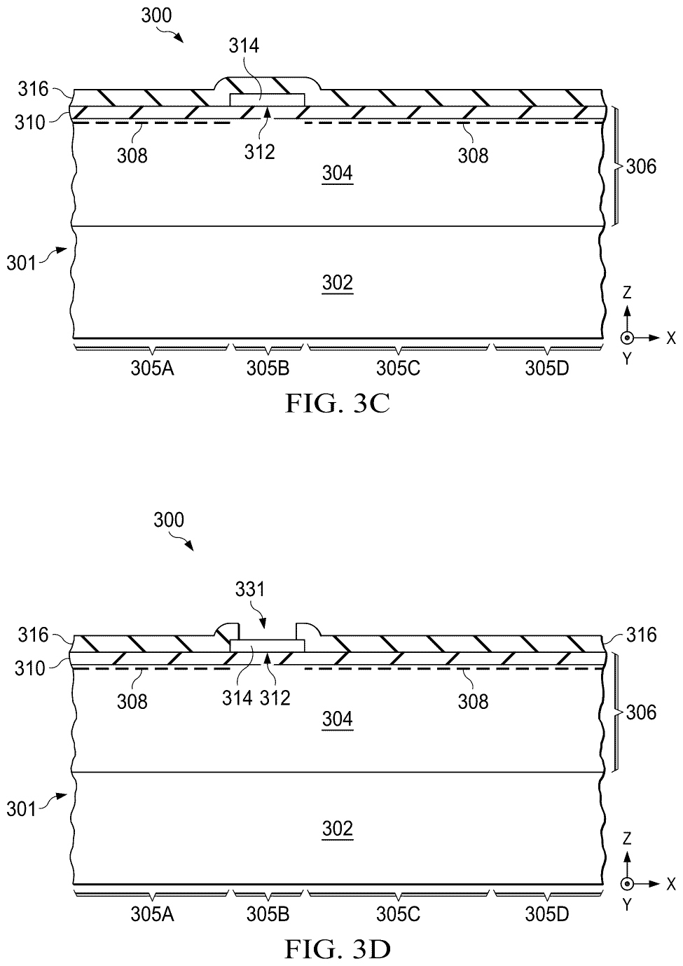

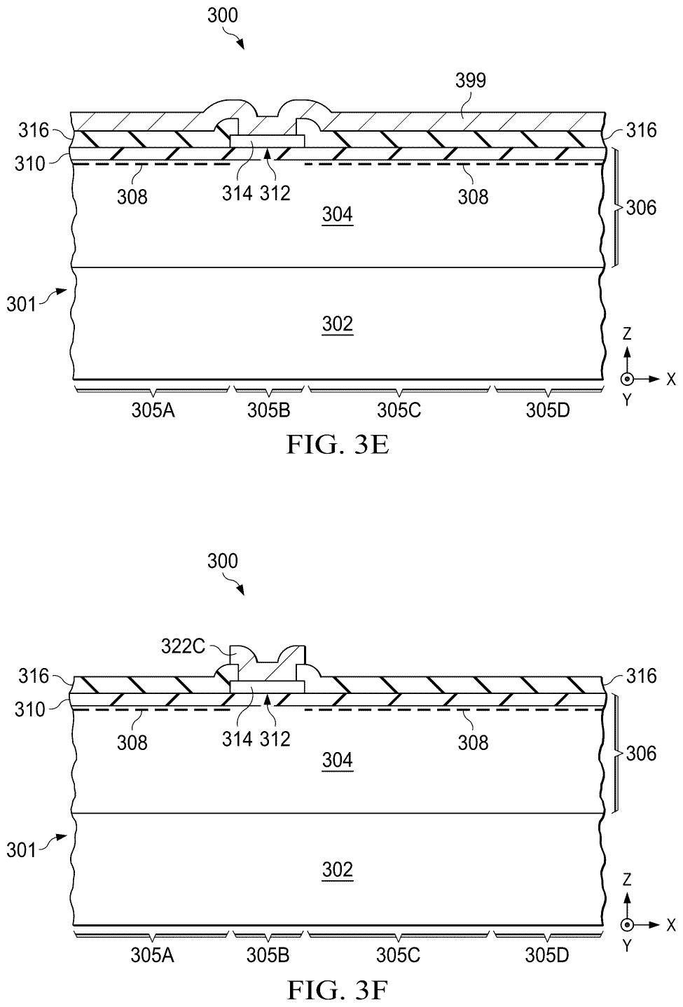

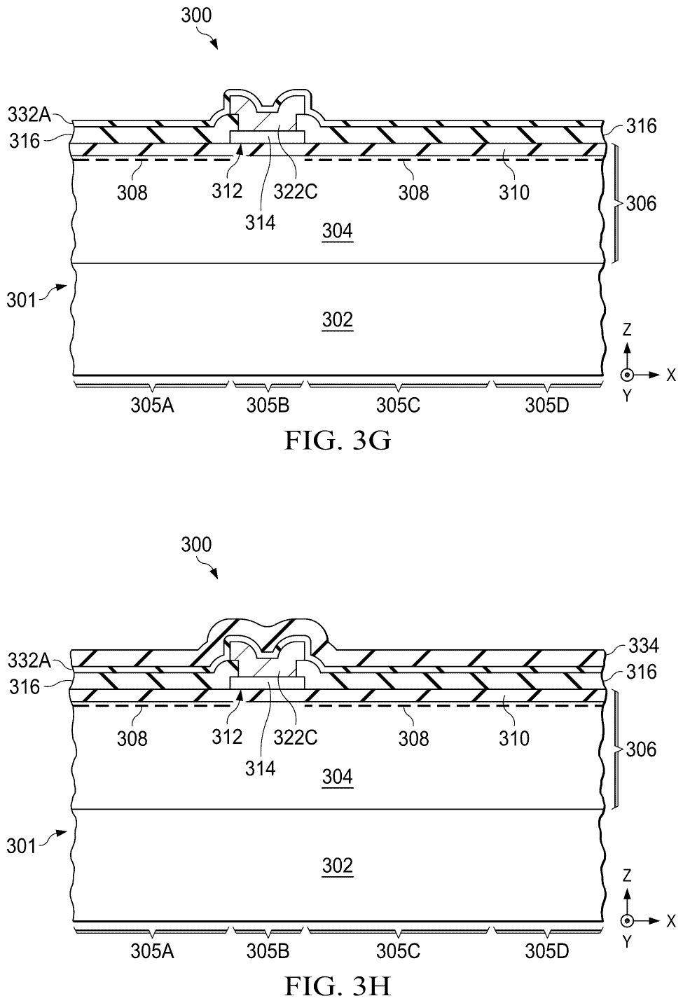

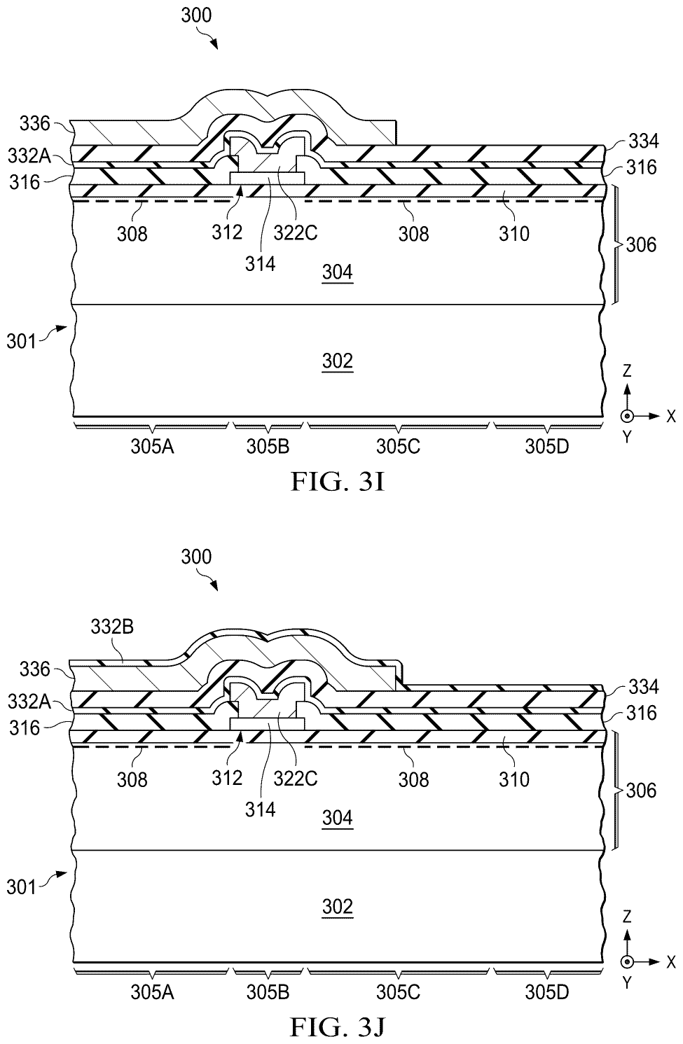

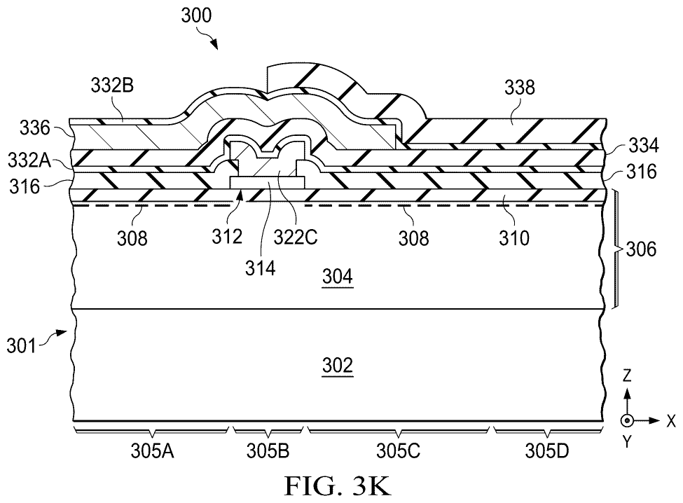

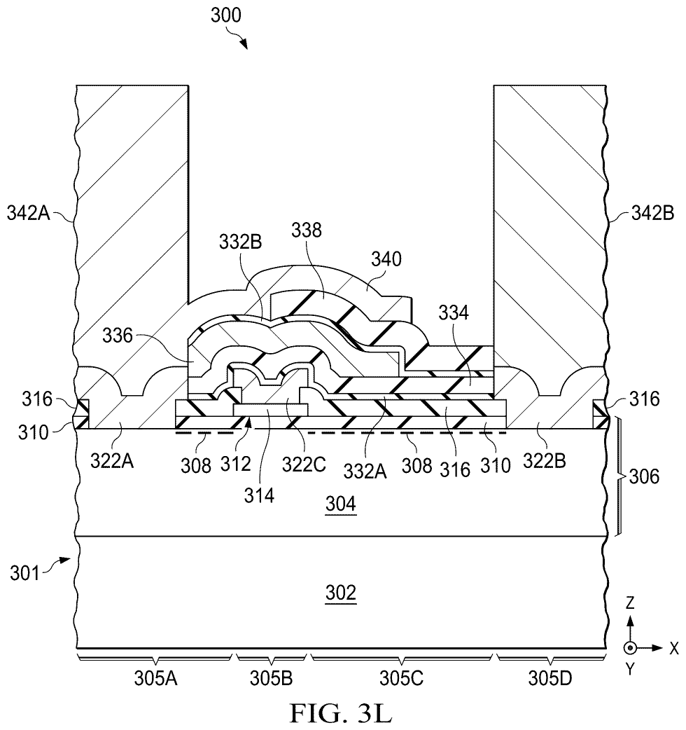

Referring to the drawings, FIGS. 3A-3L depict cross-sectional views of a semiconductor device 300 including a GaN device 301 at various stages of a gate first process flow where one or more hydrogen-blocking layers may be provided according to an example of the present disclosure. FIG. 3A depicts an early intermediate stage of the semiconductor device 300 formed on a portion of a semiconductor substrate 302, which may be provided as a silicon wafer, a silicon-on-sapphire wafer, or a silicon carbide wafer, and/or as semiconductor substrates including cores configured for matching coefficient of thermal expansion (CTE), and/or the like. A buffer layer 304 comprising one or more layers of III-N semiconductor material is formed on the substrate 302. In some examples where the substrate 302 is implemented as a silicon wafer or a sapphire wafer, the buffer layer 304 may include a nucleation layer having a stoichiometry that includes aluminum to match a lattice constant of the substrate 302. In some examples, the buffer layer 304 may further include layers/sublayers of aluminum gallium nitride (AlGaN) with decreasing aluminum content, including an unintentionally doped (UID) GaN sublayer in some arrangements. For purposes of the examples herein, the various layers/sublayers of a buffer layer, e.g., the buffer layer 304, are not specifically shown in the drawing Figures of the present disclosure.

Depending on implementation, the buffer layer 304 may have a thickness of about 1 micron (μm) to several microns, e.g., 3.5 μm to 7.0 μm, which may be formed by a suitable epitaxial process, e.g., a metal organic vapor phase epitaxy (MOVPE) process with several operations to form the various layers and/or sublayers. In some arrangements, an example buffer layer 304 may comprise a stack of multiple layers/sublayers of suitable materials and compositions (e.g., GaN, AlGaN) as noted above, where the layers/sublayers may have variable thicknesses depending on the technology and device application. In some arrangements, the buffer layer 304 may include AlGaN-based transition layers, epitaxial layers with strain-layer superlattice (SLS) structures, and the like.

The buffer layer 304 may be formed over an area of the substrate 302, where different regions such as a source region 305A, a gate region 305B, a drain region 305D and a drain access region 305C between the gate region 305B and the drain region 305D may be provided with respect to the GaN device 301. The source region 305A may be regarded as including a source access region (not specifically shown in the drawing Figures), which may refer to a region between a source electrode (e.g., source electrode 322A as shown in FIG. 3L) and the gate region 305B similar to the drain access region 305C. A channel layer may be provided as part of the buffer layer 304—e.g., a top portion of the buffer layer 304 proximate to a barrier layer 310. Whereas a channel layer may primarily include GaN material, there may be optional trace amounts of other group III elements, such as aluminum or indium, in some implementations.

A barrier layer 310 comprising III-N semiconductor material is formed over the buffer layer 304. In an example arrangement, the barrier layer 110 may have a thickness ranging from about 1 nanometer (nm) to about 60 nm, and may include aluminum and nitrogen. In some versions of this example, the barrier layer 310 may include gallium at a lower atomic percent than aluminum. In some versions, the barrier layer 310 may also include indium. In some examples, the barrier layer 310 includes an AlGaN layer.

The barrier layer 310 over the buffer layer 304 is operable as part of a heterojunction structure 306 for causing the formation of a 2DEG 308 proximate to an interface between the barrier layer 310 and the buffer layer 304. In some examples, the stoichiometry and thickness of the barrier layer 310 may be configured to provide a suitable free charge carrier density (e.g., 3×10¹² cm⁻² to 2×10¹³ cm⁻²) of the 2DEG for facilitating the device operation.

For purposes of effectuating EMODE functionality, a p-doped III-N layer 314, e.g., comprising one or more layers of III-N material, is formed over the barrier layer 310 as shown in FIG. 3A. In some examples, the p-doped III-N layer 314 may also be referred to as a p-III-N layer or a p-GaN layer. The formation of the p-GaN layer 314 causes the 2DEG to be reduced—e.g., absent in some cases. In versions of this example, the p-doped III-N layer 314 may comprise a GaN layer doped with magnesium (Mg) or other p-type dopants. In some examples, the p-doped GaN layer 114 may include a p-dopant concentration of about 1×10¹⁷ atoms/cm³ to 1×10²¹ atoms/cm³ and may have a thickness of about 10 nm to 200 nm. In some additional and/or alternative arrangements, additional layers such as an AlGaN cap layer (e.g., devoid of p-doping; not shown in the drawing Figures) may be provided over the p-GaN layer 314.

FIG. 3B depicts a stage after patterning the p-GaN layer 314 using a mask and appropriate photolithography and etch process to form a part of a gate stack 312, which may include additional capping layers (e.g., AlGaN layers) in some implementations in addition to a gate electrode to be subsequently formed over the p-GaN layer 314 (and the additional capping layers if present). As a result of patterning the p-GaN layer 314 (e.g., removing portions of the p-GaN layer 314 outside the gate region 305B), the 2DEG 308 may be established in the channel layer outside the gate region 305B. In some versions of the examples herein, the source region 305A (where a source electrode or contact is be formed) and the drain region 305D (where a drain electrode or contact is to be formed) may be asymmetrically disposed relative to the gate region 305B although it is not a requirement. For example, there may be a greater lateral distance between the gate region 305B and the drain region 305D than a lateral distance between the gate region 305B and the source region 305A by virtue of an access region, e.g., drain access region 305C, disposed between the gate region 105B and the drain region 105D. In some additional and/or alternative arrangements, a source access region may also be provided between the source region 305A and the gate region 305B in a similar manner, as previously noted, while still having source/drain region asymmetry with respect to the gate region 305B.

Although not specifically shown in FIGS. 3A and/or 3B, a suitable device isolation step may be implemented to achieve isolation with respect to the GaN device 101. Depending on implementation, an isolation step may include mesa etching, implanting, etc., to define a region where the 2DEG 308 outside the active area is absent, eliminated or otherwise disrupted. In some examples, an Ar+implant at 120 keV having a dosage around 5×10¹⁴ atoms/cm² may be implemented to achieve device isolation.

FIG. 3C depicts a stage where a dielectric layer 316 is formed over the semiconductor device 300, where the dielectric layer 316 extends over the p-GaN layer 314 in the gate region 305B as well as across the barrier layer 310 in the source region 305A, the drain access region 305C and the drain region 305D. In some versions of this example, the dielectric layer 316 comprises a SiN layer having a thickness of about of about 10 nm to 100 nm and may be operable as a surface passivation layer. In an example implementation, the dielectric layer 316, which may be referred to as a first dielectric layer in some examples, may be formed by a high temperature LPCVD process, e.g., at temperatures ranging from about 700° C. to about 850° C., using suitable precursors such as dichlorosilane (DCS) and ammonia (NH₃). In some examples, the LPCVD processing conditions may be configured to provide desirable key electrical characteristics of the GaN device 301, e.g., dynamic on-state resistance (R_{DSON}), time-dependent dielectric breakdown (TDDB), etc. Although the dielectric layer 316 is illustrated as a single layer in FIG. 3C, it is not a necessary requirement. Accordingly, the dielectric layer 316 may comprise multiple SiN layers that may be operable as a composite passivation layer in some additional and/or alternative examples. In some arrangements, the first dielectric layer 316 may comprise different materials, e.g., silicon dioxide (SiO₂), silicon oxynitride (SiON), aluminum oxide (Al₂O₃), etc., and may be formed using other techniques such as ALD. Additional details regarding the formation of dielectric layers using LPCVD processes that may be used as passivation layers in some examples may be found in U.S. Patent Application Publication No. 2023/0094094, which is incorporated by reference herein in its entirety for all purposes.

Because of the high temperatures (e.g., at temperatures ranging from about 700° C. to about 850° C.) used in some LPCVD processes, any hydrogen diffusing into the p-GaN layer 314, e.g., from the decomposed precursor species in the LPCVD reactor, may be outgassed, thus avoiding the deactivation of p-dopants in the p-GaN layer 314. As a result, a blocking layer over the p-GaN layer 314 may not be necessary prior to depositing the first dielectric layer 316 according to some examples. On the other hand, if a relatively low temperature process is used for forming the dielectric layer 316, such a process may not cause outgassing, thus resulting in hydrogen remaining in the p-GaN layer 314.

An example gate first flow as illustrated herein includes forming a gate electrode or contact in the gate region 305B first, e.g., prior to forming source and drain electrodes, which is facilitated by forming a gate contact aperture 331 over the p-GaN layer 314 in the gate region 305B as depicted in FIG. 3D. In versions of this example, a gate contact photolithography and etch process may be performed to form the aperture 331 in the first dielectric layer 316 that exposes the p-GaN layer 314. In some examples, an annealing process (e.g., at temperatures around 600° C. to 800° C. for about 1 to 2 minutes) may be optionally implemented after forming the gate contact aperture 331, which facilitates outgassing of any dopant-bound hydrogen present in the p-GaN layer 314, thus resulting in a reactivation of deactivated (e.g., hydrogen-bound) dopant species in the p-GaN layer 314.

FIG. 3E depicts a stage where a suitable conductive layer 399 is formed over the patterned dielectric layer 316 for facilitating the formation of a gate electrode. In versions of this example, the conductive layer 399 may comprise a metal layer—e.g., formed by sputtering. Depending on implementation, the conductive layer 399 may comprise one or more metals, such as titanium, nickel, tungsten, platinum, iridium, aluminum, gold, etc., and/or may include other electrically conductive materials such as carbon nanotubes or graphene as well as metallic nitrides such as titanium nitride (TiN), tantalum nitride (TaN) and the like.

FIG. 3F depicts a stage where a gate electrode or contact 322C is patterned from the conductive layer 399 based on a suitable gate lithography and etch process. FIG. 3G depicts a stage where a hydrogen-blocking layer 332A, also referred to as a first blocking layer, is formed over the gate electrode 322C as well as over the patterned dielectric layer 316. In versions of this example, the blocking layer 332A may have a thickness of about 2 nm to 20 nm and may comprise an aluminum oxide (Al₂O₃) layer, an aluminum nitride (AlN) layer, and/or a layer including a combination of both Al₂O₃ and AlN. In some arrangements, the blocking layer 332A may be deposited using a suitable ALD process depending on the material composition. For example, an AlN layer may be deposited using ALD at a temperature ranging from about 250° C. to about 350° C. with ammonia (NH₃) and trimethylaluminum (TMA) as precursors. In some examples, an Al₂O₃ layer may be deposited using ALD at similar temperatures, e.g. ranging from range of about 250° C. to about 350° C., using ozone (O₃) or water (H₂O) in combination with trimethylaluminum (TMA) as precursors. In additional and/or alternative arrangements, hydrogen-blocking layers such as the blocking layer 332A may be deposited using PVD or another technique.

FIG. 3H depicts a stage where a dielectric layer 334 is formed over the first blocking layer 332A. In some arrangements, the dielectric layer 334 may comprise a SiN layer deposited using a plasma enhanced CVD (PECVD) process, which may be performed at temperatures of around 350° C. to 400° C. that are lower than the temperatures of LPCVD used for forming the first dielectric layer 316. Depending on implementation, the second dielectric layer 334 may have a thickness ranging from tens of nanometers to several hundreds of nanometers. Because of the lower temperatures used in PECVD, the dielectric layer 334, which may also be referred to as a second dielectric layer in some examples, may include hydrogen to a greater degree (e.g., due to less outgassing) than the first dielectric layer 316. Accordingly, the hydrogen of the second dielectric layer 334 that could have diffused into the p-GaN layer 314 (e.g., through the first dielectric layer 316 near the gate region 305B) during subsequent thermal process steps (e.g., source/drain ohmic contact annealing) may be prevented from doing so because of the barrier provided by the blocking layer 332A.

In some arrangements, the second dielectric layer 334 may be operable as and configured to provide dielectric separation with respect to a field plate (FP) structure, e.g., a source FP structure, that may be formed at a subsequent stage of the process flow as an optional implementation. As illustrated in FIG. 3I, a source FP structure 336, which may also be referred to as a first FP structure in some examples, may be formed over the second dielectric layer 334 in the source region 305A and the gate region 305B, and at least partially extending over a portion of the drain access region 305C. Depending on implementation, the first FP structure 336 may have a variable thickness and comprise suitable conductive materials (e.g., metals).

Although the first FP structure 336 is shown in FIG. 3I as fully extending over the source region 305A, it is not a necessary requirement. In some additional and/or alternative examples, the first FP structure 336 may extend only partially over the dielectric layer 334 in a portion of the source region 305A. As will be seen below, regardless of whether the first FP structure 336 extends to the source electrode 322A or terminates before reaching the source electrode 322A (e.g., based on design rules relating to a source contact aperture area to be formed in the source region 305A), an additional blocking layer may be formed over the first FP structure 336 for purposes of some examples herein. Where the first FP structure 336 extends only partially in the source region 305A, it may not be connected to a source electrode 322A or terminal that may be formed at a subsequent stage.

In some arrangements, a second blocking layer 332B may be formed over the first FP structure 336 and the second dielectric layer 334 as illustrated in FIG. 3J for providing additional hydrogen diffusion barrier capability, e.g., as an optional implementation, where further PECVD-based dielectric layers may be provided. In general, a GaN process flow may include one or more blocking layers where each blocking layer may be formed prior to depositing a corresponding hydrogen-containing dielectric layer (e.g., a PECVD SiN layer) over the blocking layer. Further, where such additional blocking layers are provided, e.g., the second blocking layer 332B, the additional blocking layers may comprise a respective ALD/ALE layer having a thickness and/or material composition (e.g., Al₂O₃, AlN or a combination of both) similar to the first blocking layer 332A described above.

FIG. 3K depicts a stage where a dielectric layer 338 is formed over the second blocking layer 332B. As illustrated, the dielectric layer 338, which may be referred to as a third dielectric layer in some examples, may extend across the drain access region 305C while partially overlying the second blocking layer in the gate region 305B. Similar to the second dielectric layer 334, the third dielectric layer may be formed using PECVD and may comprise SiN or similar material that may include hydrogen susceptible to diffusion at high temperatures.

FIG. 3L depicts a more completely formed semiconductor device 300 including the GaN device 301, where source and drain electrodes 322A, 322B are formed in the source and drain regions 305A, 305B, respectively, using a contact mask and an etch process comprising wet etch and/or dry etch, followed by suitable metallization and annealing. Accordingly, the buffer layer 304 in the source region 305A and the drain region 305D may be exposed in respective apertures (not specifically shown in FIG. 3L) formed through respective source-side and drain-side stacks comprising the hydrogen-blocking layers, one or more FP structures (where extending to the source region), various dielectric layers, and the like. Thereafter, the contact apertures may be metallized using one or more metals such as titanium, nickel, tungsten, platinum, iridium, aluminum, gold, etc., as well as metallic nitrides such as TiN, TaN, and the like. Further, a source terminal 342A having a field plate structure 340, e.g., a second FP structure, a gate terminal (not shown in FIG. 3L) and a drain terminal 342B may be formed through an inter-level dielectric (ILD) and/or pre-metal dielectric (PMD) insulator layer (not shown in FIG. 3L) for facilitating electrical contact with source electrode 322A, drain electrode 322B and gate electrode 322C, respectively.

Whereas the blocking layers 332A and/or 332B are shown in the example of FIG. 3L as fully extending to the source terminal 342A, some additional and/or alternative arrangements may provide for partial extension of the blocking layers 332A and/or 332B toward the source terminal 342A. In some arrangements, the lateral extent of a hydrogen-containing dielectric layer, e.g., the dielectric layers 334 and/or 338, may determine, in part, the extent of the blocking layer disposed underneath the hydrogen-containing dielectric layer. For example, the blocking layer 332B may partially extend over the FP structure 336 underneath an overlapping portion of the dielectric layer 338 instead of covering the entire FP structure 336 in some implementations.

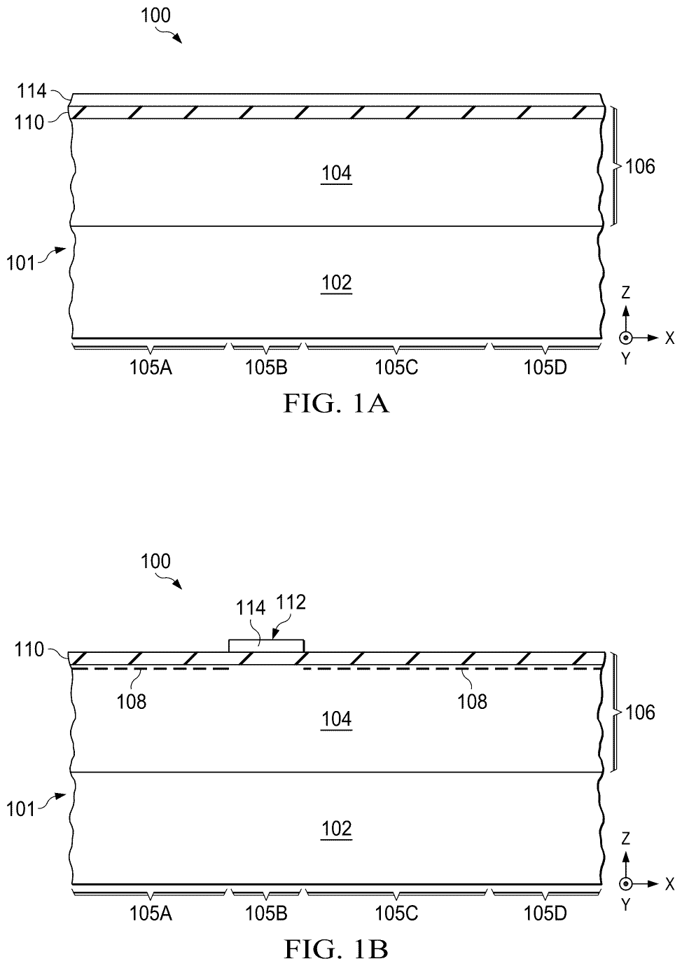

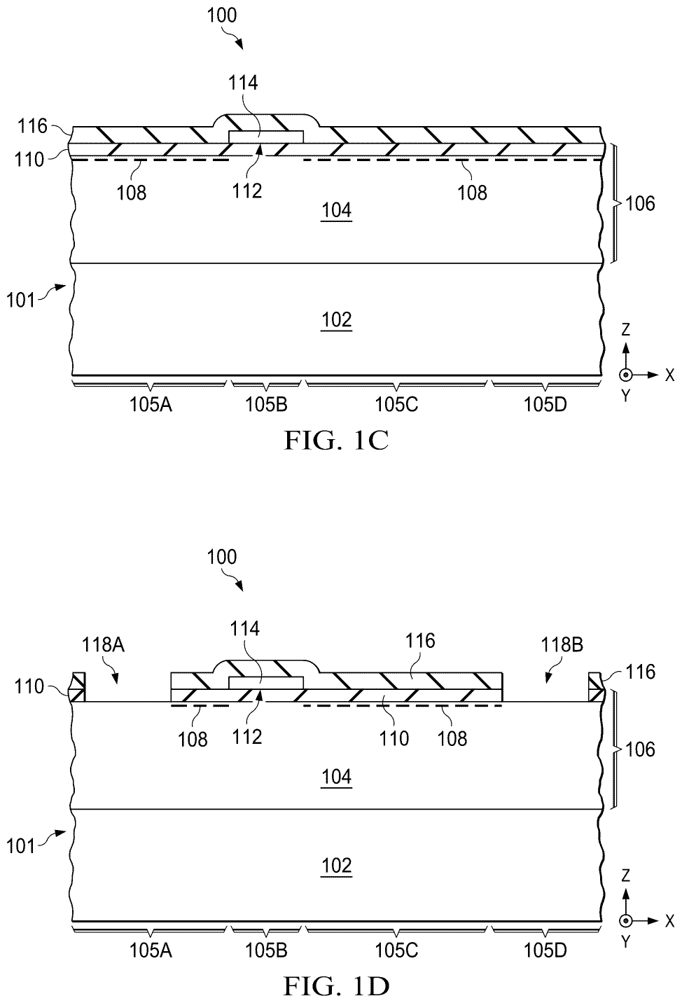

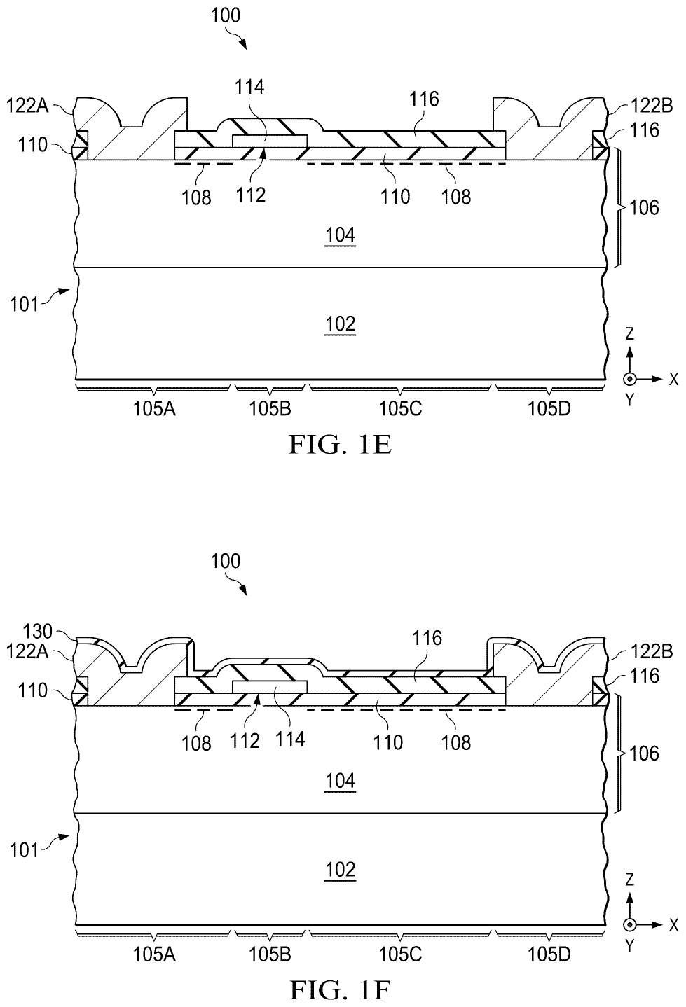

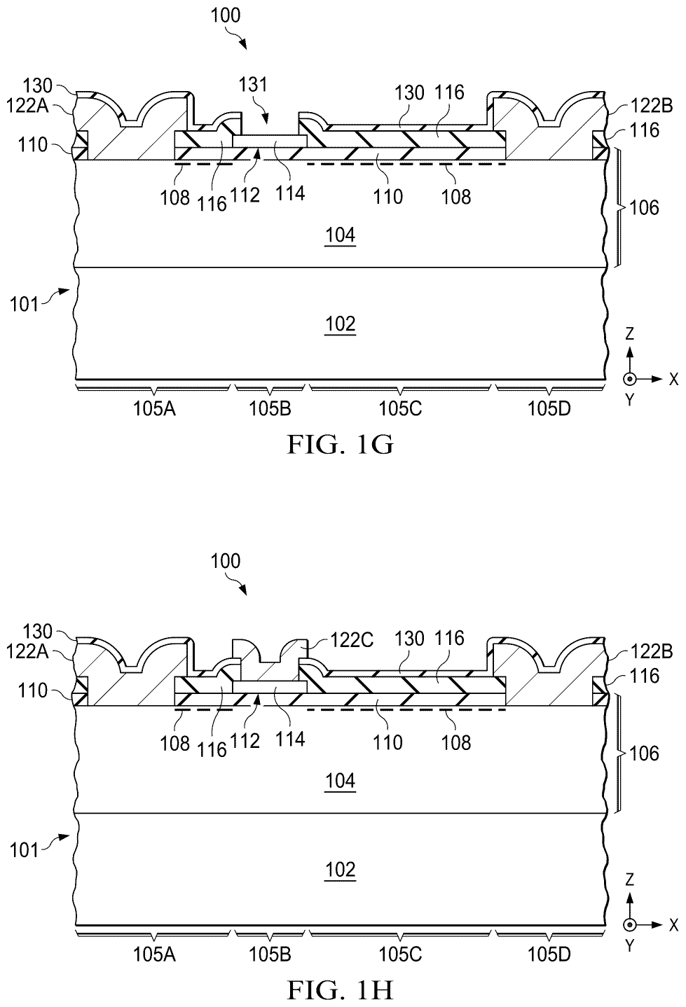

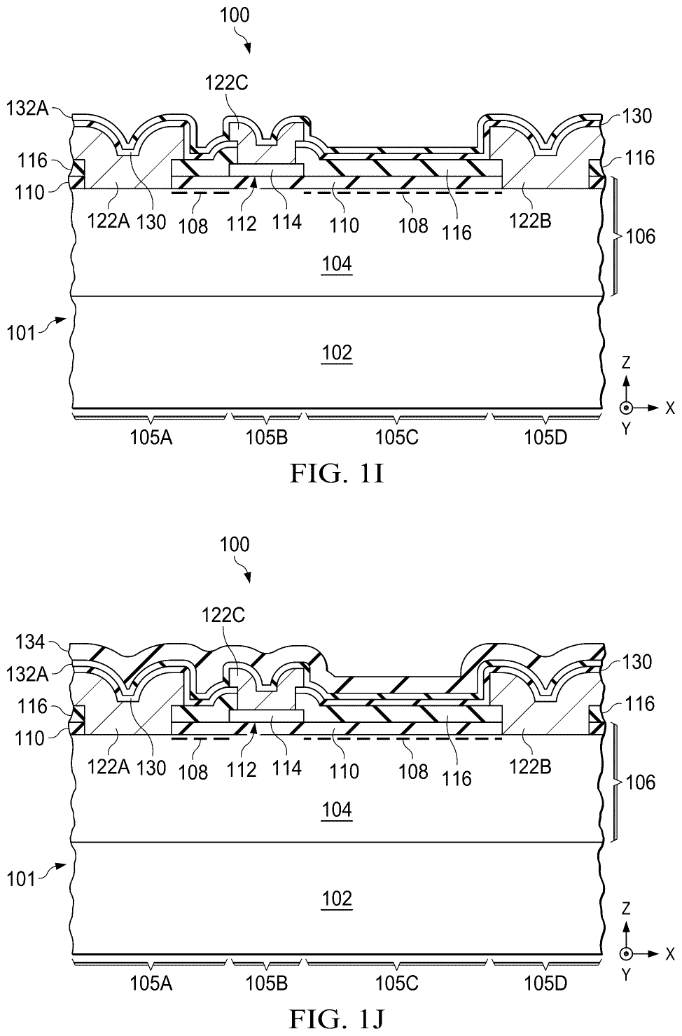

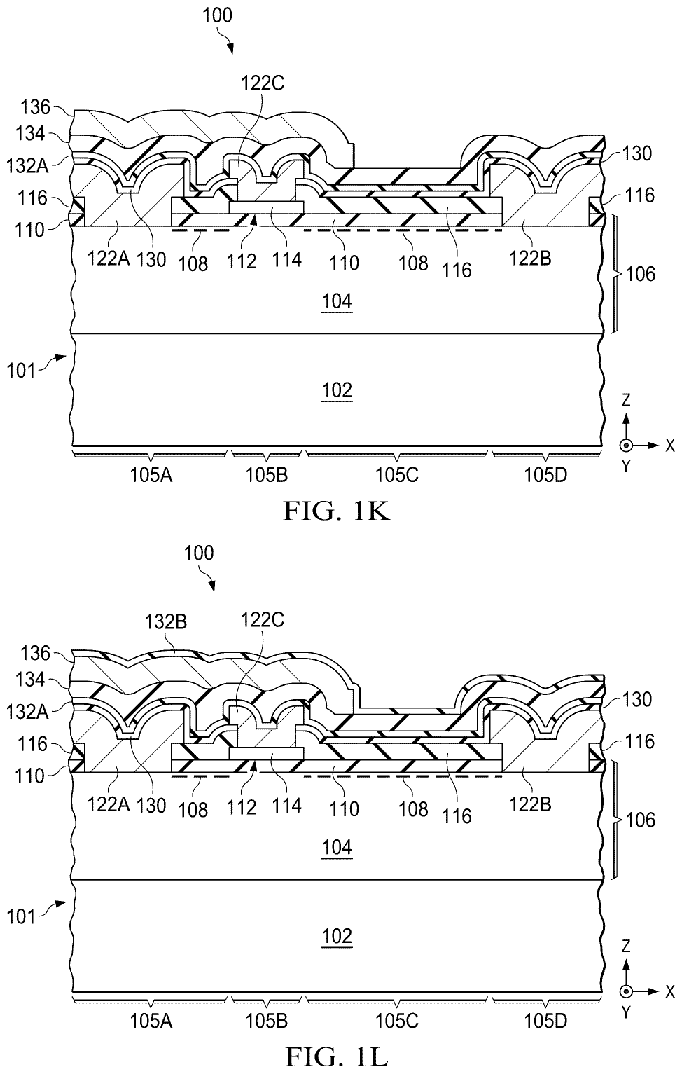

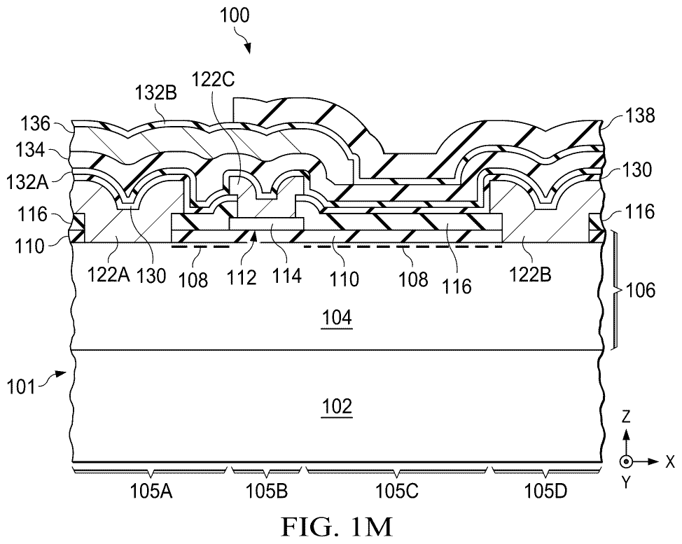

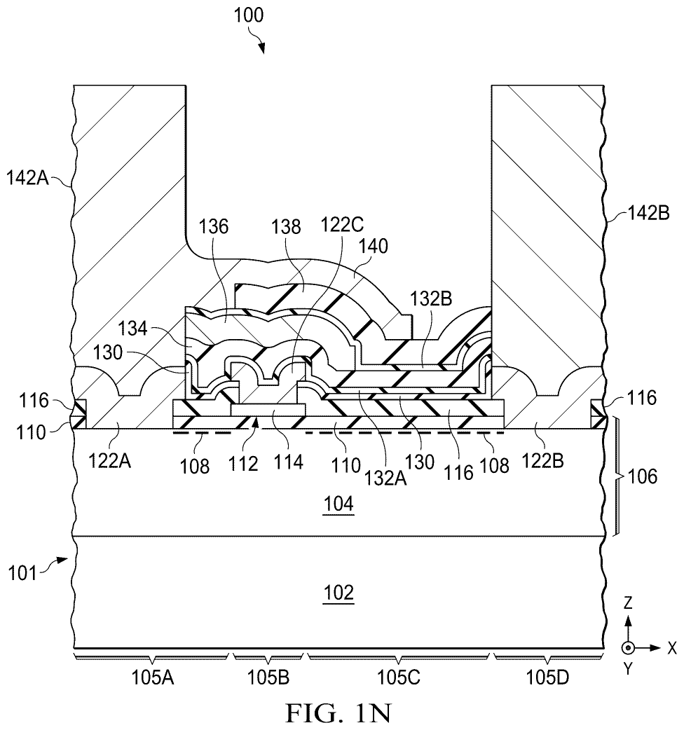

Turning to FIGS. 1A-1N, depicted therein are cross-sectional views of a semiconductor device 100 including a GaN device 101 at various stages of a gate last process flow where one or more hydrogen-blocking layers may be provided according to another example of the present disclosure. In general, some of the stages shown in FIGS. 1A-1N are substantially similar or identical to several corresponding stages of the gate first process shown in FIGS. 3A-3L. Accordingly, the description set forth above regarding the formation of hydrogen-blocking layers as well as various hydrogen-containing dielectric layers is largely applicable, in relevant parts, to the various corresponding structures and features illustrated in the cross-sectional view of FIGS. 1A-1N, which will not be repeated in detail here except as will be noted below.

Similar to the stages shown in FIGS. 3A-3C, an intermediate stage of the semiconductor device 100 includes a semiconductor substrate 102 where a source region 105A, a gate region 105B, a drain region 105D and a drain access region 105C between the gate region 105B and the drain region 105D may be provided with respect to the GaN device 101. A p-GaN layer 114 is formed over a heterojunction structure 106 disposed over the substrate 102, where the p-GaN layer 114 may be patterned over the gate region 105B as part of a gate stack 112 including a gate electrode to be formed in subsequent stages. As before, the heterojunction structure 106 includes a barrier layer 110 over a buffer layer 104, which supports a 2DEG 108 in the buffer layer 104, proximate to an interface between the barrier layer 110 and the buffer layer 104. A first dielectric layer 116, e.g., an LPCVD SiN layer, operable as a surface passivation layer similar to the passivation layer 316 is formed over the barrier layer 110 and the patterned p-GaN layer 114 in the stage shown in FIG. 1C. In additional and/or alternative arrangements, the first dielectric layer 116 may comprise SiON, SiO₂, Al₂O₃, as previously noted. Further, techniques other than LPCVD, e.g., ALD, may be used for forming the first dielectric layer 116, similar to the formation of the dielectric layer 316 as set forth in the stage of FIG. 3C.

FIG. 1D depicts a stage where source and drain contact apertures 118A, 118B are formed in the source and drain regions 105A, 105B, respectively, using a suitable contact mask and an etch process comprising wet etch and/or dry etch. FIG. 1E depicts a contact metallization and annealing stage where a source contact 122A and a drain contact 122B are formed in the source and drain regions 105A, 105B, respectively, using appropriate metals, metallic nitrides, etc., as noted previously. Because of the high temperatures used in annealing (e.g., around 700° C. for about 5 minutes in some implementations), hydrogen in the first dielectric layer 116 (if present) may be outgassed, thus avoiding and/or otherwise minimizing the risk of deactivation of the dopants in the p-GaN layer 114.

In an example gate last process, a dielectric layer 130 operable to mask and protect the source and drain electrodes 122A, 122B from subsequent processing, e.g., gate electrode formation, may be provided as set forth in FIG. 1F. Depending on implementation, the dielectric layer 130 may have a thickness of about 10 nm to 30 nm and comprise SiO₂, SiON, SiN, Al₂O₃, etc.

FIG. 1G depicts a stage where a gate electrode photolithography and etch process is performed to form an aperture 131 that exposes the p-GaN layer 114. FIG. 1H depicts a stage where a gate electrode or contact 122C is formed using suitable metallization process similar to the contact processes set forth above.

FIG. 1I depicts a stage where a first blocking layer 132A is formed over the gate electrode 122C in the gate region 105B, which may extend over the dielectric layer 130 over the source and drain electrodes 122A, 122B as well as the passivation layer 116 over the barrier layer 110. Similar to the first blocking layer 332A described above, the first blocking layer 132A in this example may comprise an ALD layer having a thickness of about 2 nm to 20 nm and may comprise Al₂O₃, AlN, and/or a combination thereof.

FIG. 1J depicts a stage where a second dielectric layer 134 is formed over the first blocking layer 132A. Analogous to the dielectric layer 334, the second dielectric layer 134 may comprise a PECVD SiN layer that may contain hydrogen. FIG. 1K depicts a stage where a first FP structure 136 is formed over the second dielectric layer 134, where the first FP structure 136 extends over the source region 105A, the gate region 105B and at least a portion of the drain access region 105C. Similar to the stage shown in FIG. 3I, the first FP structure 136 may or may not fully extend to the source electrode 122A, depending on implementation.

FIG. 1L depicts a stage where a second blocking layer 132B is formed over the first FP structure 136 and a portion of the second dielectric layer 134 that is not covered by the first FP structure 136. Similar to the arrangements set forth above, the second blocking layer 132B may comprise an ALD/ALE layer having a thickness of about 2 nm to 20 nm and may comprise Al₂O₃, AlN, and/or a combination thereof. Further, the second blocking layer 132B may be provided as an optional implementation in some examples depending on whether additional hydrogen-containing dielectric layers are provided in the process flow.

FIG. 1M depicts a stage where a third dielectric layer 138 is formed over the second blocking layer 132B, where the third dielectric layer 138 may overlap a portion of the first FP structure 136 covering the gate stack 112 in the gate region 105B and extending over the drain access region 105B and the drain region 105D. Similar to the dielectric layer 338, the third dielectric layer 138 may comprise a hydrogen-containing PECVD layer, e.g., a SiN layer.

FIG. 1N depicts a more completely formed semiconductor device 100 including the GaN device 101, where a source terminal 142A having a field plate structure 140, e.g., a second FP structure, a gate terminal (not shown in FIG. 1N) and a drain terminal 142B are formed through an ILD/PMD insulator layer (not shown in FIG. 1N) for facilitating electrical contact with source electrode 122A, drain electrode 122B and gate electrode 122C, respectively. Analogous to the example shown in FIG. 3L, the blocking layers 132A and/or 132B are shown in the example of FIG. 1N as fully extending to the source terminal 142A, although it is not a necessary requirement.

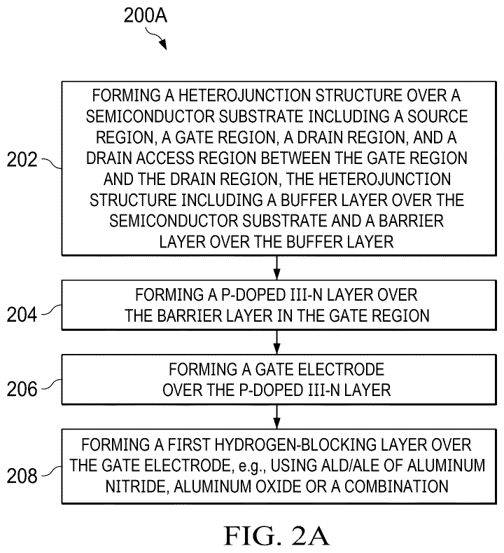

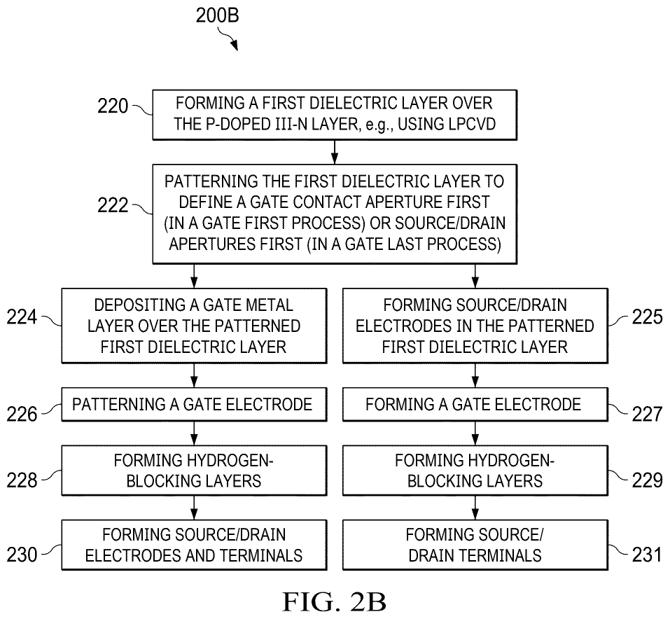

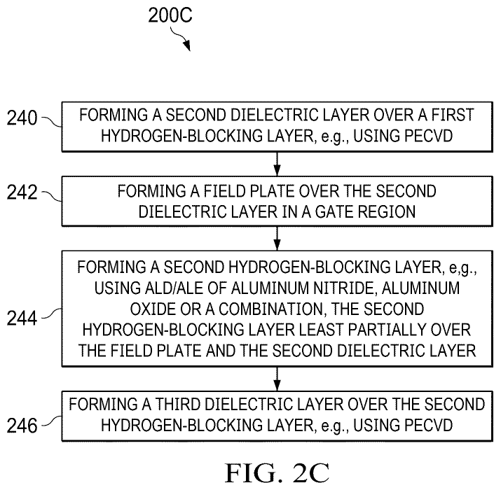

FIGS. 2A-2C are flowcharts of methods of fabricating a semiconductor device according to some examples of the present disclosure, where different steps, acts, functions and/or blocks may be combined or otherwise rearranged in multiple combinations. Method 200A shown in FIG. 2A may commence with forming a heterojunction structure over a semiconductor substrate that includes a source region, a gate region, a drain region, and a drain access region between the gate region and the drain region as set forth at block 202, which may relate to aspects of process stages shown in FIGS. 1A and 3A. At block 204, a p-doped III-N layer (e.g., a p-GaN layer) may be formed over the barrier layer in the gate region, which may relate to aspects of the stages set forth in FIGS. 1B and 3B. At block 206, a gate electrode may be formed over the p-doped III-N layer as part of forming a gate stack, which may relate to aspects of stages set forth in FIGS. 1H and 3F. At block 208, a first hydrogen-blocking layer may be formed over the gate electrode, e.g., using ALD/ALE of A1₂O₃, AlN or a combination of both, which may relate to aspects of stages set forth in FIGS. 1I and 3G.

In some examples, a first dielectric layer may be formed over the p-GaN layer as set forth at block 220 of method 200B shown in FIG. 2B, which may relate to aspects of stages set forth in FIGS. 1C and 3C. Depending on whether a gate first process or a gate last process is implemented, the first dielectric layer may be patterned to define a gate contact aperture first or source/drain contact apertures first for forming respective contacts/electrodes therein as shown at block 222. In an example gate first process, a gate metal layer may be deposited over the first dielectric layer defining the gate contact aperture, where the gate metal layer may be etched to form a gate electrode in the gate contact aperture, as set forth at blocks 224 and 226. In some arrangements, these acts may relate to aspects of stages shown in FIGS. 3D-3F. Thereafter, one or more blocking layers may be formed depending on how many hydrogen-containing dielectric layers are provided in a GaN implementation. After completing the formation of blocking layers, some of which may be optionally implemented, respective source and drain electrodes may be formed using a suitable contact metallization and annealing process as set forth at blocks 228 and 230. These acts may relate to aspects of stages shown in FIGS. 3G-3L in some arrangements.

In an example gate last process, source and drain electrodes may be formed in the first dielectric layer patterned with source and drain contact apertures as set forth at block 225, which may relate to aspects of stages shown in FIGS. 1D and 1E. A gate electrode using appropriate gate metallization may be formed in a gate aperture formed through the first dielectric layer as set forth at block 227, which may relate to aspects of stages shown in FIGS. 1G and 1H. Thereafter, one or more blocking layers may be formed (block 229) similar to the steps set forth above with respect to an example gate first process. At block 231, conductive terminals may be formed for facilitating electrical contact with the source, drain and gate electrodes, respectively. These acts may relate to aspects of stages shown in FIGS. 1I-1N in some example arrangements.

In some arrangements, regardless of whether a gate first process or a gate last process is implemented, additional blocking layers may be provided in an optional implementation as previously noted. In some examples, a second dielectric layer may be formed over a first hydrogen-blocking layer, e.g., using PECVD, as set forth at block 240 of a method 200C shown in FIG. 2C. In some examples, a field plate (FP) structure may be formed over the second dielectric layer in a gate region (block 242). In some examples, a second hydrogen-blocking layer may be formed at least partially overlapping the FP structure and extending over the second dielectric layer (block 244). In some examples, a third dielectric layer may be formed over the second hydrogen-blocking layer, e.g., using PECVD, as set forth at block 246.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), PECVD, or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. In addition, terms such as “over”, “under”, “below”, etc., relative to the spatial orientation of two components does not necessarily mean that one component is immediately or directly over the other component, or that one component is immediately or directly under or below the other component. Further, the features and/or components of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. A semiconductor device, comprising:
a semiconductor substrate including a source region, a gate region, a drain region, and a drain access region between the gate region and the drain region;
a heterojunction structure over the semiconductor substrate, the heterojunction structure including a buffer layer over the semiconductor substrate and a barrier layer over the buffer layer;
a p-doped III-N layer over the barrier layer in the gate region;
a gate electrode over the p-doped III-N layer; and
a first hydrogen-blocking layer over the gate electrode.

2. The semiconductor device of claim 1, further comprising a first dielectric layer extending from the p-doped III-N layer and over the drain access region, the first hydrogen-blocking layer extending from the gate electrode and over the first dielectric layer.

3. The semiconductor device of claim 2, wherein the first dielectric layer is a low-pressure chemical vapor deposition (LPCVD) layer comprising silicon nitride (SiN), silicon oxynitride (SiON), and/or silicon dioxide (SiO₂).

4. The semiconductor device of claim 2, further comprising:
a second dielectric layer over the first hydrogen-blocking layer;
a field plate over the second dielectric layer in the gate region;
a second hydrogen-blocking layer at least partially over the field plate and the second dielectric layer; and
a third dielectric layer over the second hydrogen-blocking layer.

5. The semiconductor device of claim 4, wherein the second and third dielectric layers each comprise a plasma-enhanced chemical vapor deposition (PECVD) layer of silicon nitride (SiN) silicon oxynitride (SiON), and/or silicon dioxide (SiO₂).

6. The semiconductor device of claim 1, wherein the first hydrogen-blocking layer is an atomic layer deposition (ALD) layer comprising at least one of aluminum oxide (Al₂O₃) and aluminum nitride (AlN).

7. The semiconductor device of claim 6, wherein the ALD layer has a thickness of about 2 nm to 20 nm.

8. The semiconductor device of claim 1, wherein the p-doped III-N layer is a GaN layer having a thickness of about 10 nm to 200 nm.

9. The semiconductor device of claim 1, wherein the p-doped III-N layer is a GaN layer doped with magnesium (Mg) having a concentration of about 1×10¹⁷ atoms/cm³ to 1×10²¹ atoms/cm³.

10. A method, comprising:
forming a heterojunction structure over a semiconductor substrate including a source region, a gate region, a drain region, and a drain access region between the gate region and the drain region, the heterojunction structure including a buffer layer over the semiconductor substrate and a barrier layer over the buffer layer;
forming a p-doped III-N layer over the barrier layer in the gate region;
forming a gate electrode over the p-doped III-N layer; and
forming a first hydrogen-blocking layer over the gate electrode.

11. The method of claim 10, further comprising forming, before forming the gate electrode, a first dielectric layer extending from the p-doped III-N layer and over the drain access region, the first hydrogen-blocking layer extending from the gate electrode and over the first dielectric layer.

12. The method of claim 11, further comprising:
forming a second dielectric layer over the first hydrogen-blocking layer;
forming a field plate over the second dielectric layer in the gate region;
forming a second hydrogen-blocking layer at least partially over the field plate and the second dielectric layer; and
forming a third dielectric layer over the second hydrogen-blocking layer.

13. The method of claim 12, wherein the first and second hydrogen-blocking layers each comprise an atomic layer deposition (ALD) layer of at least one of aluminum oxide (Al₂O₃) and aluminum nitride (AlN).

14. The method of claim 13, wherein the ALD layer has a thickness of about 2 nm to 20 nm.

15. The method of claim 13, wherein the ALD layer is deposited at a temperature range of about 250° C. to 350° C. using precursors comprising ammonia (NH₃) and trimethylaluminum (TMA).

16. The method of claim 13, wherein the ALD layer is deposited at a temperature range of about 250° C. to 350° C. using precursors comprising ozone (O₃) and trimethylaluminum (TMA).

17. The method of claim 12, wherein the first dielectric layer is a low-pressure chemical vapor deposition (LPCVD) layer comprising silicon nitride (SiN) silicon oxynitride (SiON), and/or silicon dioxide (SiO₂).

18. The method of claim 12, wherein the second and third dielectric layers each comprise a plasma-enhanced chemical vapor deposition (PECVD) layer of silicon nitride (SiN) silicon oxynitride (SiON), and/or silicon dioxide (SiO₂).

19. The method of claim 10, wherein the gate electrode is formed before forming source and drain electrodes in the source and drain regions, respectively, of the semiconductor substrate.

20. The method of claim 10, wherein the p-doped III-N layer is a GaN layer doped with magnesium (Mg) having a concentration of about 1×10¹⁷ atoms/cm³ to 1×10²¹ atoms/cm³.
